(19) United States
(12) Patent Application Publication
(10) Pub. No.: US 2020/0220054 A1
(43) Pub. Date: Jul. 9, 2020

(54) ANTIREFLECTIVE STRUCTURES FOR LIGHT EMITTING DIODES

(71) Applicant: Glint Photonics, Inc., Burlingame, CA (US)

(72) Inventor: Andrew Kim, San Jose, CA (US)

(21) Appl. No.: 16/736,131

(22) Filed: Jan. 7, 2020

Related U.S. Application Data
(60) Provisional application No. 62/788,964, filed on Jan. 7, 2019.

(51) Int. Cl. H01L 33/50; H01L 25/075; H01L 33/20

(52) U.S. Cl. CPC H01L 33/505; H01L 25/0753; H01L 33/20; H01L 2933/0058; H01L 2933/0033; H01L 2933/0041; H01L 33/502

(57) ABSTRACT

A light emitting diode chip or array of such chips is covered by a polymer layer that may include particles of phosphor or other materials to alter the spectrum of light. A surface of the polymer layer has a moth-eye structure. Sheets of polymer may be produced with the moth-eye texture imparted on one side via nano-imprint, embossing, or other procedures, which may then be laminated onto the LED or an LED Chip on Board (COB) array. In another approach, a smooth sheet of polymer is laminated onto the LED or COB array and then embossed or imprinted with the moth-eye structure. The moth-eye structure may further comprise the curved surface of a dome, produced, for example, using a dome-shaped mold that includes the moth-eye structure.

### CROSS REFERENCE TO RELATED APPLICATIONS

This application claims priority to a co-pending U.S. Provisional Application entitled “Antireflective structures for light emitting diodes”, Ser. No. 62/788,964 filed Jan. 7, 2019, the entire contents of which are hereby incorporated by reference.

### TECHNICAL FIELD

This patent application relates to optics, specifically to optical structures for minimizing reflection on light emitting diodes.

### BACKGROUND

Light-emitting diodes (LEDs) are broadly used in lighting systems as an energy-efficient, long-lived light source. They are often packaged by placing the LED chip into a polymer encapsulant or disposing a polymer layer onto the surface of the chip. The polymer is frequently made of silicone, epoxy, or resin, and may have phosphor or other particles embedded within it in order to change the emitted spectrum. Some LED packages are formed with a flat surface, and in some cases a dome-shaped polymer structure is created on the LED package to act as a lens. Another way that LEDs are packaged is in chip-on-board (COB) configuration. In this case, the LED chips are mounted onto a circuit board in an array, and a polymer layer (such as phosphor-loaded silicone) may be applied on the entire array. In all these cases, the emitted light must transit the interface between the polymer layer (with a refractive index typically between 1.4 and 1.5) into air (refractive index=1) as it exits the LED package. The change in refractive index at this interface results in Fresnel reflections, causing a fraction of the light striking the interface to be reflected back toward the LED chip, where much of it is re-absorbed and therefore lost.

Structured antireflective materials have been studied for many years. Such surfaces contain texturing on a size-scale below the wavelength of visible light, with the structure often resembling conoids or pillars. Such surfaces create an effective gradient refractive index at the transition between solid material and air, greatly reducing the Fresnel reflections that result from abrupt transitions at smooth interfaces. This sort of texturing is often called a “moth-eye” pattern because it mimics the natural structures found in the eyes of moths.

Prior art such as U.S. Pat. No. 9,240,529 and US2010/0273280A1 have described the texturing of LED semiconductor surfaces and/or phosphor-layer surfaces to enhance light extraction. Such texturing can reduce total internal reflection at the semiconductor surface and increase extraction of light from the device. This prior art texturing operates by locally changing the angle at which a light ray intersects the interface; to achieve this effect, the texturing must be on a size scale greater than the wavelength of light, in order to remain in the regime of geometric optics. This is fundamentally distinct from structured antireflective texturing, which operates in the regime of wave optics and requires texturing on a size scale smaller than the wavelength of light. Structured antireflective texturing does not reduce total internal reflection, but does reduce Fresnel reflections at smooth interfaces.

### SUMMARY

With the approach described herein, moth-eye type structures are applied to various LED package types to reduce reflections and improve overall efficiency of the LED package.

In accordance with one embodiment, an LED package consists of an LED chip and a laminated layer of silicone containing phosphor, wherein the surface of the silicone layer that is opposite the LED chip has a moth-eye type structure to minimize optical reflections.

### BRIEF DESCRIPTION OF THE DRAWINGS

A further understanding of the nature and advantages of this approach may be realized by reference to the remaining portions of the specification and the drawings.

FIG. 1(a) is a perspective view of an example moth-eye structured surface with conoid structures.

FIG. 1(b) is a perspective view of an example moth-eye structured surface with cylindrical pillar structures.

FIG. 2(a) is a cross-section view of a light emitted diode (LED) covered by a polymer layer with a moth-eye structure on its surface.

FIG. 2(b) is a cross-section view of an LED covered by a polymer layer with embedded particles to alter the spectrum of light and a moth-eye structure on its surface.

FIG. 2(c) is a cross-section view of an LED covered by a polymer layer with embedded particles to alter the spectrum of light and a second polymer layer with a moth-eye structure on its surface.

FIG. 3(a) is a cross-section view of an LED covered by a domed polymer layer with a moth-eye structure on its surface.

FIG. 3(b) is a cross-section view of an LED covered by a domed polymer layer with embedded particles to alter the spectrum of light and a moth-eye structure on its surface.

FIG. 3(c) is a cross-section view of an LED covered by a polymer layer with embedded particles to alter the spectrum of light and a domed polymer layer with a moth-eye structure on its surface.

FIG. 4(a) is a cross-section view of an LED array on a circuit board, with the LEDs covered by a polymer layer with a moth-eye structure on its surface.

FIG. 4(b) is a cross-section view of an LED array on a circuit board. The LEDs are covered by a polymer layer with embedded particles to alter the spectrum of light and a moth-eye structure on its surface.

FIG. 4(c) is a cross-section view of an LED array on a circuit board. The LEDs are covered by a polymer layer with embedded particles to alter the spectrum of light and a second polymer layer with a moth-eye structure on its surface.

### DETAILED DESCRIPTION OF ONE OR MORE EMBODIMENTS

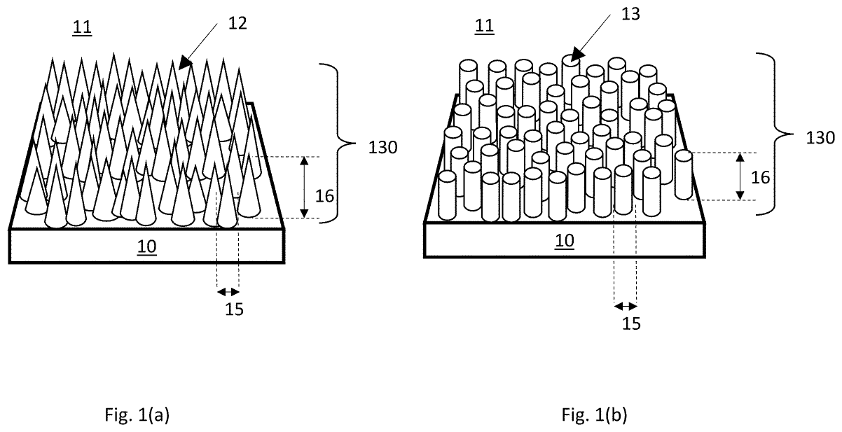

FIG. 1(a) shows an example of a moth-eye structured surface 130 as used herein, wherein a polymer material 10 has a dense array of conoid structures 12 at the interface between the polymer and air 11. FIG. 1(b) shows an example where the structure is formed with pillar shapes 13. These are example structures, and many other structure types are possible. For example, the arrangement of conoid structures 12 may be random, as in FIG. 1(a), or may alternatively be arranged in regularly spaced, repeating arrays. Also, for example, the structure may be the negative of that shown in FIG. 1(a) and FIG. 1(b), i.e. conoid or pillar-shaped holes rather than protrusions. In the embodiments described herein, the characteristic width dimension 15 is smaller than the wavelength of visible light (i.e. smaller than ˜420 nm). The characteristic height dimension 16 is preferably larger than the characteristic width dimension 15. These moth-eye structures are typically produced by imprinting, embossing or molding from a master pattern.

As used herein, the designator 130 indicates a surface with a moth-eye texture. The moth-eye structure 130 may, in one embodiment, be a layer of polymer material with moth-eye texture such as that shown in FIG. 1(a) and FIG. 1(b), where the polymer material is distinct from the material of any underlying layers. The moth-eye structure 130 may, therefore, further contain additional underlying transparent carrier layers. Alternatively, the designator 130 may indicate a moth-eye structure formed as a moth-eye surface texture formed within the material of the underlying layer.
1. Domeless LED packages

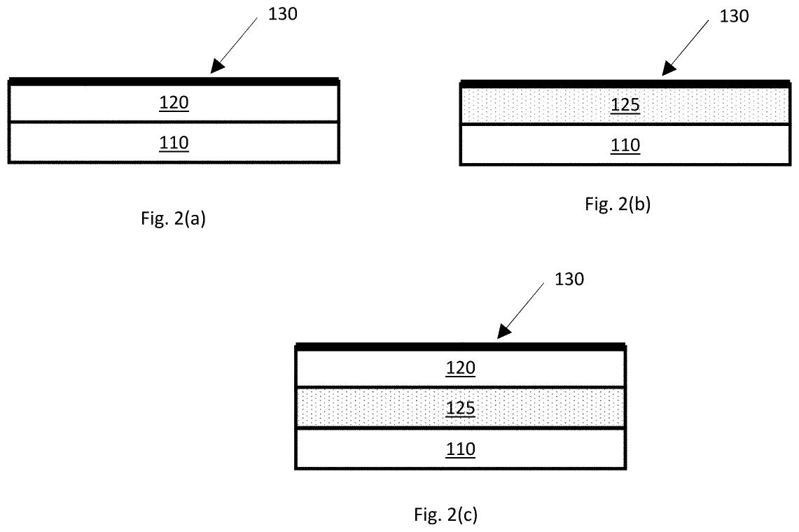

FIG. 2(a) shows an embodiment comprising an LED chip 110 with a polymer layer 120 disposed over a light emitting surface of the LED chip 110, and a moth-eye structure 130 disposed on the surface of the polymer layer 120 opposite the LED chip 110.

FIG. 2(b) shows an embodiment comprising an LED chip 110, a phosphor layer 125 disposed over a light emitting surface of the LED chip 110, and a moth-eye structure 130 disposed on the surface of the phosphor layer 125 opposite the LED chip 110. The phosphor layer 125 modifies light emitted by the LED chip 110 by converting all or a portion of the light emitted by LED chip 110 to a spectrum different from that emitted by the LED chip 110 and may also alter its angular distribution. The phosphor layer 125 may comprise a solid piece of phosphor material; alternatively, the phosphor layer 125 may comprise a polymer material that includes phosphor particles; alternatively, the phosphor layer 125 may comprise a glass material that includes phosphor particles. The phosphor layer 125 may also comprise additional materials to modify the optical, thermal, and mechanical performance of the phosphor layer 125.

Other embodiments may comprise a plurality of layers on an LED chip 110, including ones where the moth-eye structure 130 is disposed on a layer other than the phosphor layer 125. For example, FIG. 2(c) shows an embodiment comprising an LED chip 110, a first flat phosphor layer 125 disposed over a light-emitting surface of the LED chip 110, and a flat polymer layer 120 is disposed over the surface of phosphor layer 125 opposite the LED chip 110. A moth-eye structure 130 is disposed on the surface of the polymer layer 120 opposite the LED chip 110.
2. Domed LED packages

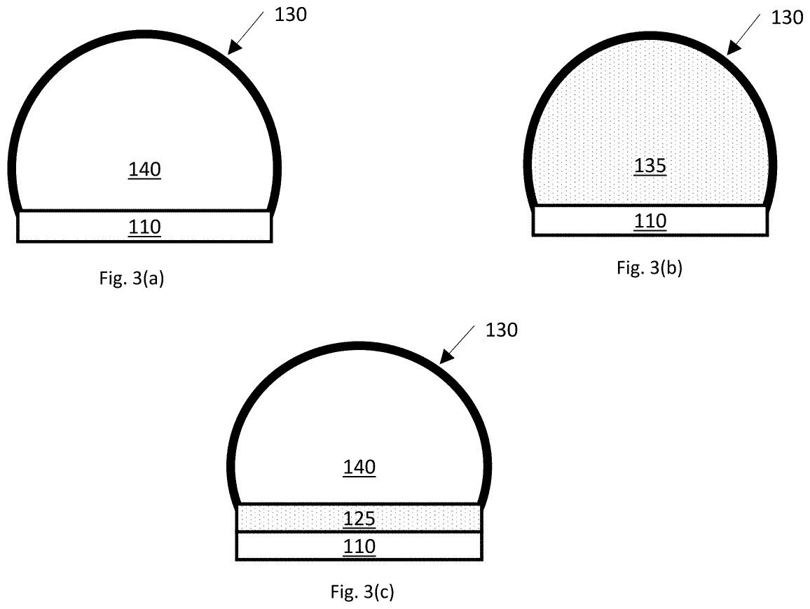

FIG. 3(a) shows an embodiment comprising an LED chip 110, a domed polymer layer 140 that forms a dome disposed over the LED chip 110, and a moth-eye structure 130 disposed over the domed surface of the polymer layer 140. The layer 140 may alternatively be composed of glass.

FIG. 3(b) shows an embodiment comprising an LED chip 110, a domed polymer layer 135 comprising particles of phosphor or other materials that modify light emitted by the LED chip 110 disposed over the LED chip 110. The surface of the domed polymer 135 layer has a moth-eye structure 130 disposed over it. The layer 135 may alternatively be composed of glass.

FIG. 3(c) shows an embodiment comprising an LED chip 110, a flat phosphor layer 125 disposed over a light-emitting surface of the LED chip 110, and a domed polymer layer 140 with a moth-eye structure 130 disposed over the domed surface of the polymer layer 140. The layer 140 may alternatively be composed of glass.
3. Chip-on-board (COB) packages

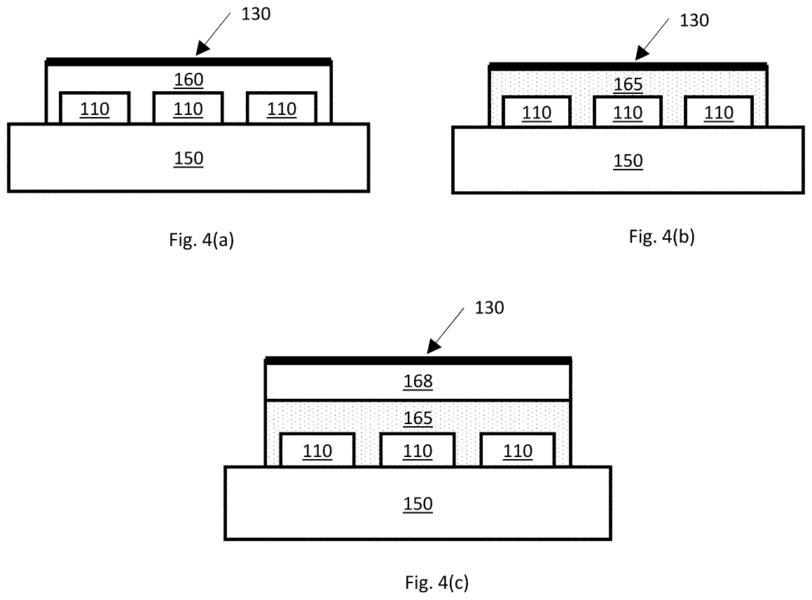

FIG. 4 (a) shows an embodiment comprising an array of LED chips 110 attached to a circuit board 150, a common polymer layer 160 disposed over the array of LED chips 110, and a moth-eye structure 130 disposed over the surface of the polymer layer 160 opposite the array of LED chips 110.

FIG. 4(b) shows an embodiment comprising an array of LED chips 110 attached to a circuit board 150, a common phosphor layer 165 disposed over the LED chips 110, and a moth-eye structure 130 disposed over the surface of the phosphor layer 165 opposite the array of LED chips 110.

FIG. 4(c) shows an embodiment comprising an array of LED chips 110 attached to a circuit board 150, a common phosphor layer 165 disposed over the LED chips 110, an additional common polymer layer 168 disposed over the phosphor layer 125, and a moth-eye structure 130 disposed on the polymer layer 168.
4. Fabrication

The polymer materials discussed in this invention are preferably highly transparent and robust in high-temperature operation. For this reason, silicone formulations may be preferred. Epoxies and other transparent resins may also be preferred.

The moth-eye structure 130 on flat surfaces, such as those shown in FIGS. 2(a)-2(c) and FIGS. 4(a)-4(c), may be formed in a number of ways. A first fabrication approach is to initially produce sheets of polymer with the moth-eye structure 130 imparted on one side via nano-imprint, embossing, or other processes, and to then laminate the sheet onto the LED or COB and cure it in place. The moth-eye structure 130 may be directly formed into the material of the polymer sheets; alternatively, the moth-eye structure may be formed of a liquid resin that is then cured on a pre-fabricated polymer sheet that acts as a mechanical carrier. Lamination may be achieved by several different methods. An optically-clear adhesive (OCA) may be disposed between the polymer sheets with moth-eye structure 130 and underlying layers; the OCA may be applied to the polymer sheets with moth-eye structure 130 during their fabrication; alternatively, the OCA may be dispensed onto the underlying layers before applying the polymer sheets with moth-eye structure 130. Alternatively, the polymer sheets with moth-eye structure 130 may have a surface that is not fully cured until after it is applied to the underlying layers.

A second fabrication approach is to first dispose a smooth layer of polymer onto the underlying layers and then emboss or imprint the moth-eye structure. Other fabrication approaches are also possible.

The embodiments such as that shown in FIGS. 3(a)-3(c) require a moth-eye structure on the curved surface of a dome. Polymer sheets with moth-eye structure 130 may be laminated onto the domed surface. The moth-eye structure 130 may alternatively be formed by using a dome-shaped mold that includes the negative of the desired moth-eye structure 130.

FIGS. 2(a)-2(c), FIGS. 3(a)-3(c), and FIGS. 4(a)-4(c) show moth-eye textures on surfaces that are otherwise smooth. However, the surfaces may be optionally made to include macro-scale texturing or curvature, at a size scale that is substantially larger than the characteristic width and height dimensions of the moth-eye texture. In that case, the moth-eye structure 130 is made to conform to the macro-scale surface.

Other materials or particles which may be used in place of the phosphor include dyes, quantum dots, scattering materials of different refractive index such as TiO₂, SiO₂, etc.

These examples are not exhaustive, and other useful implementations of the invention will be evident to those skilled in the art.

1. An apparatus comprising:
a light emitting diode (LED);
a light-transmissive material layer, disposed adjacent the LED; and
wherein a surface of the light-transmissive material layer has a moth-eye type structure.

2. The apparatus of claim 1 additionally comprising:
a phosphor, disposed between the LED and the moth-eye type structure.

3. The apparatus of claim 2 wherein the phosphor is disposed in the light-transmissive material layer.

4. The apparatus of claim 2 wherein the phosphor is disposed in a second layer different from the light-transmissive material layer.

5. The apparatus of claim 1 wherein the light-transmissive layer and LED are formed as a laminate.

6. The apparatus of claim 1 wherein the light-transmissive layer is dome-shaped.

7. The apparatus of claim 1 further comprising:
one or more additional LEDs disposed adjacent the light-transmissive layer.

8. A method comprising, in any order:
providing a planar light emitting diode (LED) having a light emitting surface;
disposing a polymer layer adjacent the light emitting surface; and
forming a moth-eye structure on the polymer layer.

9. The method of claim 8 additionally comprising:
disposing a light spectrum-altering material on or in the polymer layer.

10. The method of claim 9 wherein the light spectrum-altering material is disposed in another layer separate from the polymer layer.

11. The method of claim 8 wherein the polymer layer is dome-shaped.

12. The method of claim 8 further comprising:
providing one or more additional LEDs with light emitting surfaces; and
the polymer layer is also disposed adjacent the light emitting surfaces of the additional LEDs.

13. The method of claim 8 wherein the moth-eye pattern is formed via nano-printing or embossing.
